(19) United States
(12) Patent Application Publication
(10) Pub. No.: US 2019/0372034 A1
(43) Pub. Date: Dec. 5, 2019

(54) DISPLAY DEVICE

(71) Applicant: Sharp Kabushiki Kaisha, Sakai City, Osaka (JP)

(72) Inventors: Seiji KANEKO, Sakai City (JP); Yohsuke KANZAKI, Sakai City (JP); Takao SAITOH, Sakai City (JP); Masahiko MIWA, Sakai City (JP); Masaki YAMANAKA, Sakai City (JP)

(21) Appl. No.: 16/462,554

(22) PCT Filed: Aug. 4, 2017
(86) PCT No.: PCT/JP2017/028454

§ 371 Date: May 21, 2019

(51) Int. Cl. H01L 51/00; H01L 51/52; H01L 27/32

(52) U.S. Cl. CPC H01L 51/0097; H01L 2251/5338; H01L 27/3276; H01L 51/524

(57) ABSTRACT

At a bending section of a frame region, an insulating film with a groove formed on a front surface of the insulating film is provided, the groove extending in a direction intersecting one side of a display region on a terminal section side, and a frame wiring line is provided, at the bending section, to be bent to intersect the groove between the insulating film and a protection film.

### TECHNICAL FIELD

The disclosure relates to a display device.

### BACKGROUND ART

In recent years, organic EL display devices, which use organic electroluminescence (EL) elements and are of the self-luminous type, have attracted attention as a display device that can replace the liquid crystal display device. As the organic EL display device, a flexible organic EL display device, in which an organic EL element, a variety of films or the like is layered on a flexible resin substrate, has been proposed. In the organic EL display device, a rectangular display region for displaying an image and a frame region formed around the display region is provided, where reduction of the frame region is demanded. In the flexible organic EL display device, for example, if the frame region is reduced by bending the frame region located on the terminal side, the wiring line arranged in the frame region may be broken.

For example, PTL 1 discloses a light-emitting device in which a wiring line having an uneven shape in a sectional view are provided in an expandable and contractible region.

### CITATION LIST

### Patent Literature

PTL 1: JP 2016-136515 A

### SUMMARY

### Technical Problem

Incidentally, for example, as disclosed in PTL 1, a wiring line arranged in the frame region on the terminal side, which has an uneven shape in a sectional view, may cause the wiring line to be broken in bending about an axis not exactly orthogonal to a direction in which the wiring line extends, while preventing breakage of the wiring line in bending about an axis exactly orthogonal to a direction in which the wiring line extends, thus, there is room for improvement.

The disclosure has been made in view of the above, and an object of the disclosure is to prevent breakage of a wiring line in bending about an axis exactly orthogonal to a direction in which the wiring line extends, as well as in bending about an axis not exactly orthogonal to a direction in which the wiring line extends.

### Solution to Problem

In order to achieve the above object, a display device according to the disclosure includes a resin substrate, a light-emitting element configuring a display region provided on the resin substrate, the display region being formed in a rectangular shape, a frame region provided around the display region, a terminal section provided at an end portion of the frame region, a bending section provided between the display region and the terminal section, a frame wiring line provided in the frame region, the frame wiring line extending to the terminal section with being connected to the light-emitting element, and a protection film provided to cover the frame wiring line, wherein at the bending section, an insulating film with a groove formed on a front surface of the insulating film is provided, the groove extending in a direction intersecting one side of the display region on the terminal section side, and the frame wiring line is provided, at the bending section, to be bent to intersect the groove between the insulating film and the protection film.

### Advantageous Effects of Disclosure

According to the disclosure, at the bending section of the frame region, an insulating film with a groove formed on a front surface of the insulating film is provided, the groove extending in a direction intersecting one side of a display region on a terminal section side, and a frame wiring line is provided, at the bending section, to be bent to intersect the groove between the insulating film and the protection film, thus making it possible to prevent breakages of a wiring line in bending about an axis exactly orthogonal to a direction in which the wiring line extends, as well as in bending about an axis not exactly orthogonal to a direction in which the wiring line extends.

### BRIEF DESCRIPTION OF DRAWINGS

FIG. 1 is a plan view of an organic EL display device according to a first embodiment of the disclosure.

FIG. 2 is a cross-sectional view of the organic EL display device taken along line II-II in FIG. 1.

FIG. 3 is a cross-sectional view illustrating an organic EL layer included in the organic EL display device according to the first embodiment of the disclosure.

FIG. 4 is a plan view illustrating a frame region of the organic EL display device according to the first embodiment of the disclosure.

FIG. 5 is a cross-sectional view of a frame region of the organic EL display device taken along the line V-V in FIG. 4.

FIG. 6 is a cross-sectional view of a frame region of the organic EL display device taken along the line VI-VI in FIG. 4.

FIG. 7 is a plan view illustrating a frame region of an organic EL display device according to a second embodiment of the disclosure.

FIG. 8 is a plan view illustrating a frame region of the organic EL display device according to a third embodiment of the disclosure.

FIG. 9 is a plan view illustrating a frame region of a first organic EL display device according to another embodiment of the disclosure.

FIG. 10 is a plan view illustrating a frame region of a second organic EL display device according to another embodiment of the disclosure.

FIG. 11 is a plan view illustrating a frame region of a third organic EL display device according to another embodiment of the disclosure.

### DESCRIPTION OF EMBODIMENTS

Embodiments of the disclosure will be described below in detail with reference to the drawings. The disclosure is not limited to the embodiments described below.

### First Embodiment

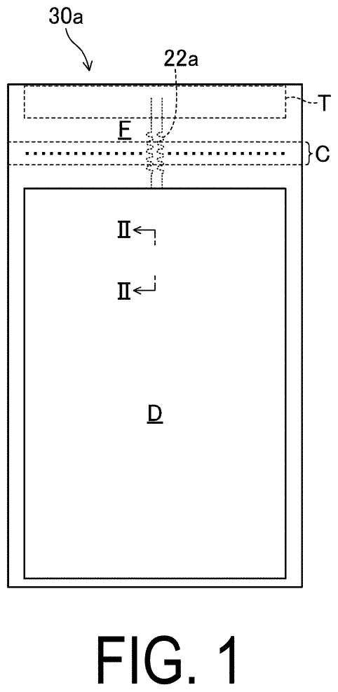

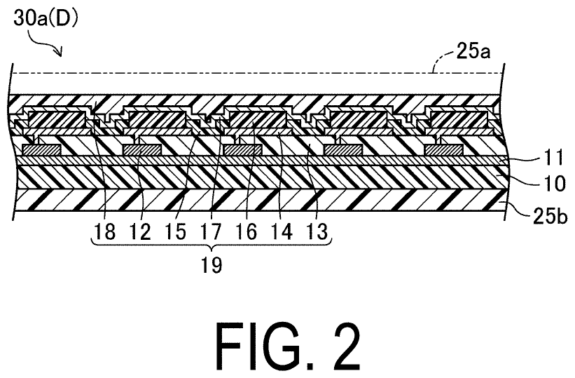

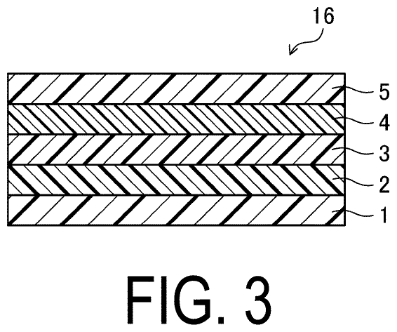

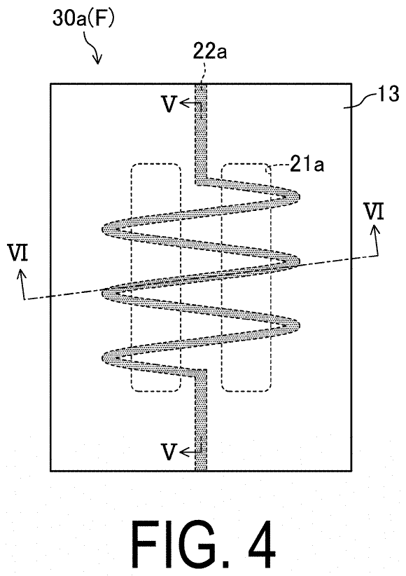

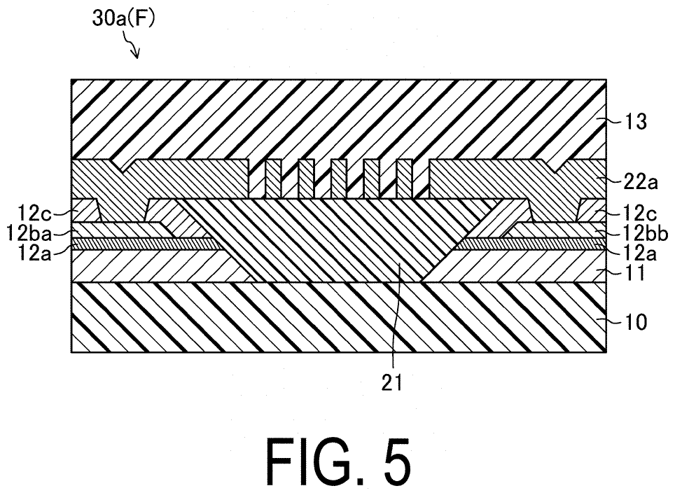

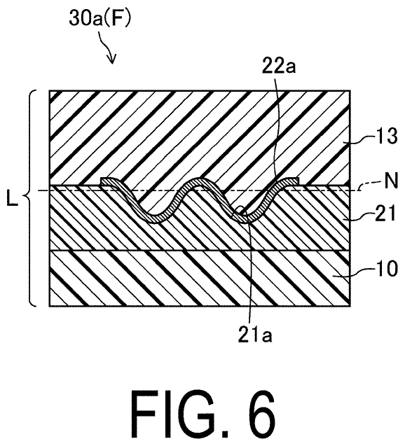

FIG. 1 to FIG. 6 illustrate a first embodiment of a display device according to the disclosure. Note that, in each of the following embodiments, an example of an organic EL display device equipped with organic EL elements is given as a display device equipped with light-emitting elements. FIG. 1 is a plan view of an organic EL display device 30a according to the first embodiment. FIG. 2 is a cross-sectional view of the organic EL display device 30a taken along line II-II in FIG. 1. FIG. 3 is a cross-sectional view illustrating an organic EL layer 16 included in the organic EL display device 30a. FIG. 4 is a plan view illustrating a frame region F of the organic EL display device 30a. FIG. 5 and FIG. 6 are cross-sectional views of the frame region F of the organic EL display device 30a taken along line V-V and line VI-VI in FIG. 4.

As illustrated in FIG. 1, the organic EL display device 30a includes a display region D for displaying an image, defined in a rectangular shape, and the frame region F defined around the display region D. As illustrated in FIG. 2, the display region D of the organic EL display device 30a is provided with organic EL elements 19, and in the display region D, a plurality of pixels are arranged in a matrix pattern. Note that each of the pixels in the display region D includes, for example, a subpixel for display of red grayscale, a subpixel for display of green grayscale, and a subpixel for display of blue grayscale. These subpixels are disposed adjacent to one another. As illustrated in FIG. 1, a terminal section T is provided in a rectangular shape at the upper end portion of the frame region F in the figure. Further, as illustrated in FIG. 1, between the display region D and the terminal section T in the frame region F, a bending section C bendable at 180 degrees (in a U shape) with a bending axis being the horizontal direction in the figure is provided to be along one side (upper side in the figure) of the display region D.

As illustrated in FIG. 2, the organic EL display device 30a includes, in the display region D, a resin substrate layer 10, a base coat film 11 provided on the front surface of the resin substrate layer 10, an organic EL element 19 provided on the front surface of the base coat film 11, and a back surface side protection layer 25b provided on the back surface of the resin substrate layer 10.

The resin substrate layer 10, which is formed of, for example, a polyimide resin or the like with a thickness of approximately from 10 μm to 20 μm, is provided as a resin substrate.

The base coat film 11 is formed with, for example, a single layer film or a multilayer film of an inorganic insulating film such as a silicon nitride film, a silicon oxide film, a silicon oxynitride film, or the like.

As illustrated in FIG. 2, the organic EL element 19 includes a plurality of TFTs 12, a flattening film 13, a plurality of first electrodes 14, an edge cover 15, a plurality of organic EL layers 16, a second electrode 17, and a sealing film 18, which are provided in the order stated, over the base coat film 11.

The plurality of TFTs 12 are provided on the base coat film 11 to correspond to the plurality of subpixels. The TFT 12 includes, for example, semiconductor layers provided in an island pattern on the base coat film 11, a gate insulating film 12a (see FIG. 5) provided to cover the semiconductor layers, a gate electrode provided to partially overlap with the semiconductor layers on the gate insulating film 12a, an interlayer insulating film 12c (see FIG. 5) provided to cover the gate electrode, and a source electrode and a drain electrode provided in a manner spaced apart from each other on the interlayer insulating film 12c. Note that, although in the first embodiment, the top-gate type is described as an example of the TFT 12, the TFT 12 may be of the bottom-gate type.

As illustrated in FIG. 2, the flattening film 13 is provided to cover a portion other than a part of a drain electrode of each TFT 12. The flattening film 13 is formed of, for example, an organic resin material, such as a polyimide resin.

As illustrated in FIG. 2, the plurality of first electrodes 14 are provided, each corresponding to each subpixel, in a matrix pattern over the flattening film 13. Here, as illustrated in FIG. 2, the first electrode 14 is coupled to the drain electrode of the TFT 12 via a contact hole formed through the flattening film 13. The first electrode 14 functions to inject holes into the organic EL layer 16. It is further preferable that the first electrodes 14 includes a material having a large work function to improve the hole injection efficiency into the organic EL layer 16. Examples of materials that may be included in the first electrode 14 include metal materials, such as silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). Further examples of materials that may be included in the first electrode 14 include alloys, examples of which include magnesium (Mg)-copper (Cu), magnesium (Mg)-silver (Ag), sodium (Na)-potassium (K), astatine (At)-astatine oxide (AtO₂), lithium (Li)-aluminum (Al), lithium (Li)-calcium (Ca)-aluminum (Al), and lithium fluoride (LiF)-calcium (Ca)-aluminum (Al). Further examples of materials that may be included in the first electrode 14 include electrically conductive oxides, examples of which include tin oxide (SnO), zinc oxide (ZnO), indium tin oxide (ITO), and indium zinc oxide (IZO). The first electrode 14 may include a stack of two or more layers of any of the above-mentioned materials. Note that, examples of materials having a large work function include indium tin oxide (ITO) and indium zinc oxide (IZO).

As illustrated in FIG. 2, the edge cover 15 is provided in a lattice pattern and surrounds the outer perimeter portion of each first electrode 14. Examples of materials that may be included in the edge cover 15 include an inorganic film, for example, a silicon oxide (SiO₂) film, a silicon nitride (SiNx (x is a positive number)) film such as a trisilicon tetranitride (Si₃N₄) film, or a silicon oxynitride (SiON) film; and an organic film, for example, a polyimide resin film, an acrylic resin film, a polysiloxane resin film, or a novolak resin film.

As illustrated in FIG. 2, the plurality of organic EL layers 16 are provided in a matrix pattern, each being arranged on each first electrode 14 and each corresponding to each subpixel. As illustrated in FIG. 3, the organic EL layers 16 each include a hole injection layer 1, a hole transport layer 2, a light-emitting layer 3, an electron transport layer 4, and an electron injection layer 5, which are provided in the order stated, over the first electrode 14.

The hole injection layer 1 is also referred to as an anode buffer layer, and functions to reduce the energy level difference between the first electrode 14 and the organic EL layer 16, to improve the hole injection efficiency into the organic EL layer 16 from the first electrode 14. Examples of materials that may be included in the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 functions to improve the efficiency of hole transport from the first electrode 14 to the organic EL layer 16. Examples of materials that may be included in the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons recombine when a voltage is applied via the first electrode 14 and the second electrode 17, the holes and electrons are injected from the first electrode 14 and the second electrode 17, respectively. The light-emitting layer 3 is formed of a material having high light-emitting efficiency. Examples of materials that may be included in the light-emitting layer 3 include metal oxinoid compounds (8-hydroxyquinoline metal complexes), naphthalene derivatives, anthracene derivatives, diphenyl ethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 functions to facilitate efficient migration of the electrons to the light-emitting layer 3. Examples of materials that may be included in the electron transport layer 4 include organic compounds, example of which include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron injection layer 5 functions to reduce the energy level difference between the second electrode 17 and the organic EL layer 16, to improve the efficiency of electron injection into the organic EL layer 16 from the second electrode 17. Because of this function, the driving voltage for the organic EL element 19 can be reduced. Note that the electron injection layer 5 is also referred to as a cathode buffer layer. Examples of materials that may be included in the electron injection layer 5 include inorganic alkaline compound such as lithium fluoride (LiF), magnesium fluoride (MgF₂), calcium fluoride (CaF₂), strontium fluoride (SrF₂), or barium fluoride (BaF₂); aluminum oxide (Al₂O₃); and strontium oxide (SrO).

As illustrated in FIG. 2, the second electrode 17 is disposed to cover the organic EL layers 16 and the edge cover 15. The second electrode 17 functions to inject electrons into the organic EL layer 16. It is further preferable that the second electrode 17 includes a material having a small work function to improve the efficiency of electron injection into the organic EL layer 16. Examples of materials that may be included in the second electrode 17 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). Further examples of materials that may be included in the second electrode 17 include alloys, examples of which include magnesium (Mg)-copper (Cu), magnesium (Mg)-silver (Ag), sodium (Na)-potassium (K), astatine (At)-astatine oxide (AtO₂), lithium (Li)-aluminum (Al), lithium (Li)-calcium (Ca)-aluminum (Al), and lithium fluoride (LiF)-calcium (Ca)-aluminum (Al). Further examples of materials that may be included in the second electrode 17 include electrically conductive oxides, examples of which include tin oxide (SnO), zinc oxide (ZnO), indium tin oxide (ITO), and indium zinc oxide (IZO). The second electrode 17 may include a stack of two or more layers of any of the above-mentioned materials. Note that, examples of materials having a small work function include magnesium (Mg), lithium (Li), lithium fluoride (LiF), magnesium (Mg)-copper (Cu), magnesium (Mg)-silver (Ag), sodium (Na)-potassium (K), lithium (Li)-aluminum (Al), lithium (Li)-calcium (Ca)-aluminum (Al), and lithium fluoride (LiF)-calcium (Ca)-aluminum (Al).

As illustrated in FIG. 2, the sealing film 18 is provided to cover the second electrode 17, and functions to protect the organic EL layer 16 from moisture and oxygen. Examples of materials that may be included in the sealing film 18 include inorganic materials, examples of which include silicon oxide (SiO₂), aluminum oxide (Al₂O₃), silicon nitride (SiNx (x is a positive number)) such as trisilicon tetranitride (Si₃N₄), and silicon carbon nitride (SiCN); and organic materials, examples of which include acrylate, polyurea, parylene, polyimide, and polyamide.

The back surface side protection layer 25b is formed of, for example, a polyethylene terephthalate (PET) resin or the like with a thickness of approximately 75 μm.

As illustrated in FIG. 4 to FIG. 6, the organic EL display device 30a includes, in the frame region F, the resin substrate layer 10, an insulating film 21 provided in contact with the front surface of the resin substrate layer 10, a frame wiring line 22a provided on the front surface of the insulating film 21, and the flattening film 13 provided as a protection film to cover the frame wiring line 22a. The base coat film 11, the gate insulating film 12a, and the interlayer insulating film 12c that are arranged in the display region D are also provided in the most part of the frame region F, but are not provided, as illustrated in FIG. 5, at the bending section of the terminal section T partially formed in the frame region F. The back surface side protection layer 25b arranged in the display region D is also provided in the most part of the frame region F, but is not provided, as illustrated in FIG. 5, at the bending section C of the frame region F.

The insulating film 21 is formed with, for example, an organic insulating film such as a polyimide resin film with a thickness of approximately 2 μm. On the front surface of the insulating film 21, a plurality of grooves 21a are formed to extend in a direction (vertical direction in FIG. 1) intersecting (for example, orthogonal to) one side of the display region D on the terminal section T side. The groove 21a has, for example, a width of approximately 6 μm, a length of approximately 1.5 mm, and a depth of approximately 0.5 μm, and includes a side surface inclined at approximately 45 degrees relative to the front surface of the insulating film 21.

As illustrated in FIG. 5, the frame wiring line 22a is connected, via a first gate conductive layer 12ba, to a signal wiring line (for example, gate line, source line, and power supply line) of the organic EL element 19 in the display region D. Further, as illustrated in FIG. 5, the frame wiring line 22a is connected to a second gate conductive layer 12bb provided to extend to the terminal section T. The frame wiring line 22a is formed with, for example, a metal layered film of a titanium film (with a thickness of approximately 100 nm)/an aluminum film (with a thickness of approximately 700 nm)/a titanium film (with a thickness of approximately 50 nm). Note that, although in the first embodiment, the example of the frame wiring line 22a formed with a metal layered film is given, the frame wiring line 22a may also be formed with a metal single layer film. As illustrated in FIG. 4, the frame wiring line 22a is provided to be bent in a wavy form to intersect multiple times at the bending section C with a pair of grooves 21a adjacent to each other in a plan view between the insulating film 21 and the flattening film 13. As illustrated in FIG. 6, the frame wiring line 22a is also provided to be bent in a wavy form to stride across, in a cross-sectional view, a neutral surface N of a layered body L over the insulating film 21. The neutral surface N is a surface that is not subject to compression nor tension, and is substantially free of bending stress, when the layered body L including the resin substrate layer 10, the insulating film 21, the frame wiring line 22a, and the flattening film 13 is caused to be bent.

The organic EL display device 30a described above has flexibility, and is configured, in each subpixel, such that the light-emitting layer 3 of the organic EL layer 16 is caused to appropriately emit light via the TFT 12 so that images are displayed.

The organic EL display device 30a of the first embodiment can be manufactured as described below.

For example, the organic EL display device 30a can be manufactured in such a way that a base coat film 11 and an organic EL element 19 are formed, using a well-known method, on the front surface of a resin substrate layer 10 formed on a glass substrate, a front surface side protection layer 25a is applied to the organic EL element 19 via an adhesive layer, a back surface side protection layer 25b is applied to the back surface of the resin substrate layer 10, from which the glass substrate has been peeled off, via an adhesive layer, and then the front surface side protection layer 25a and the adhesive layer under the front surface side protection layer 25a are removed. The frame wiring line 22a of the frame region F is formed when the source electrode and the drain electrode of the TFT 12 that are included in the organic EL element 19 are formed. The insulating film 21 in the frame region F is formed, before the formation of the source electrode and the drain electrode of the TFT 12 that are included in the organic EL element 19, by forming and patterning using a halftone mask, a graytone mask, or the like, a photosensitive organic insulating film such as a polyimide resin film in the frame region F alone.

As described above, according to the organic EL display device 30a of the first embodiment, the frame wiring line 22a intersects in a plan view with the pair of grooves 21a between the insulating film 21 and the flattening film 13, and thus, the frame wiring line 22a is provided to be bent in a wavy form to stride across, in a cross-sectional view, the neutral surface N of the layered body L. Accordingly, at the bending section C of the organic EL display device 30a, configurations (see FIG. 6) in each of which the frame wiring line 22a being bent in a wavy form to stride across, in a cross-sectional view, the neutral surface N of the layered body L are to be successively provided in a direction obliquely intersecting the direction (short-side direction of the terminal section T) in which the frame wiring line 22a extends. This makes it possible to prevent breakages of the frame wiring line 22a in bending about bending axes being provided in the long-side direction and in the short-side direction of the terminal section T, thus making it possible to prevent breakages of the frame wiring line 22a in bending about an axis exactly orthogonal to a direction in which the frame wiring line 22a extends, as well as in bending about an axis not exactly orthogonal to a direction in which the frame wiring line 22a extends.

### Second Embodiment

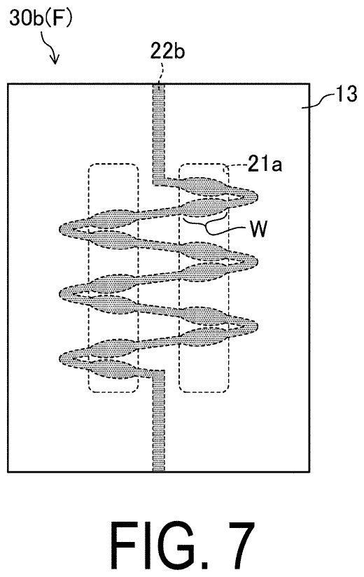

FIG. 7 illustrates a second embodiment of the display device according to the disclosure. FIG. 7 is a plan view illustrating a frame region F of an organic EL display device 30b according to the second embodiment of the disclosure. Note that, in the following embodiments, portions identical to those in FIG. 1 to FIG. 6 are denoted by the same reference signs, and their detailed descriptions are omitted.

In the first embodiment, the example of the organic EL display device 30a in which the frame wiring line 22a is provided in a uniform thickness is given. However, in the second embodiment, an example of the organic EL display device 30b provided with a frame wiring line 22b including a thick line portion W is given.

The organic EL display device 30b, like the organic EL display device 30a of the first embodiment, includes a display region D for displaying an image, defined in a rectangular shape, and the frame region F defined around the display region D.

The display region D of the organic EL display device 30b has the same configuration as in the organic EL display device 30a of the first embodiment.

The organic EL display device 30b includes, in the frame region F, the resin substrate layer 10, an insulating film 21 provided in contact with the front surface of the resin substrate layer 10, the frame wiring line 22b provided on the front surface of the insulating film 21, and a flattening film 13 provided as a protection film to cover the frame wiring line 22b.

The frame wiring line 22b is connected, via the first gate conductive layer 12ba, to a signal wiring line (for example, gate line, source line, and power supply line) of the organic EL element 19 in the display region D. The frame wiring line 22b is connected to the second gate conductive layer 12bb provided to extend to the terminal section T. The frame wiring line 22b is also formed with, for example, a metal layered film of a titanium film (with a thickness of approximately 100 nm)/an aluminum film (with a thickness of approximately 700 nm)/a titanium film (with a thickness of approximately 50 nm). As illustrated in FIG. 7, the frame wiring line 22b is provided to be bent in a wavy form to intersect multiple times at the bending section C with a pair of grooves 21a adjacent to each other in a plan view between the insulating film 21 and the flattening film 13. Further, as illustrated in FIG. 7, the frame wiring line 22b includes a thick line portion W formed at the bottom of the groove 21a thicker than the portions formed exterior to the groove 21a. The frame wiring line 22b is provided to be bent in a wavy form to stride across, in a cross-sectional view, the neutral surface N of the layered body L over the insulating film 21.

The organic EL display device 30b described above has flexibility as the organic EL display device 30a of the first embodiment, and is configured, in each subpixel, such that the light-emitting layer 3 of the organic EL layer 16 is caused to appropriately emit light via the TFT 12 so that images are displayed.

The organic EL display device 30b of the second embodiment can be manufactured, by modifying the pattern shapes of the frame wiring line 22a, in the method for manufacturing the organic EL display device 30a of the first embodiment.

As described above, according to the organic EL display device 30b of the second embodiment, the frame wiring line 22b intersects in a plan view with the pair of grooves 21a between the insulating film 21 and the flattening film 13, and thus, the frame wiring line 22b is provided to be bent in a wavy form to stride across, in a cross-sectional view, the neutral surface N of the layered body L. Accordingly, at the bending section C of the organic EL display device 30b, configurations in each of which the frame wiring line 22b being bent in a wavy form to stride across, in a cross-sectional view, the neutral surface N of the layered body L are to be successively provided in a direction obliquely intersecting the direction (short-side direction of the terminal section T) in which the frame wiring line 22b extends. This makes it possible to prevent breakages of the frame wiring line 22b in bending about bending axes being provided in the long-side direction and in the short-side direction of the terminal section T, thus making it possible to prevent breakages of the frame wiring line 22b in bending about an axis exactly orthogonal to a direction in which the frame wiring line 22b extends, as well as in bending about an axis not exactly orthogonal to a direction in which the frame wiring line 22b extends.

The organic EL display device 30b of the second embodiment, in which the frame wiring line 22b includes the thick line portion W formed at the bottom of the groove 21a thicker than the portions formed exterior to the groove 21a, makes it possible to reduce the wiring line resistance of the frame wiring line 22b and to further prevent breakage of the frame wiring line 22b.

### Third Embodiment

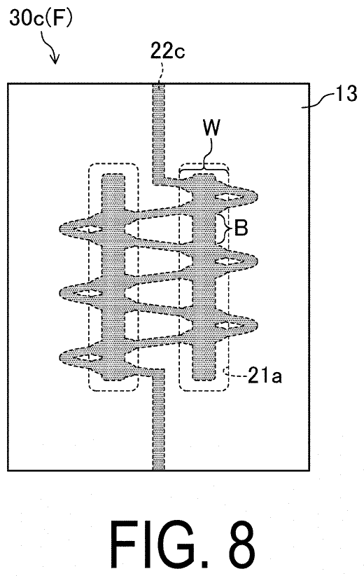

FIG. 8 illustrates a third embodiment of the display device according to the disclosure. FIG. 8 is a plan view illustrating a frame region F of an organic EL display device 30c according to the third embodiment.

In the second embodiment, the example of the organic EL display device 30b provided with the frame wiring line 22b including the thick line portion W is given. However, in the third embodiment, an example of the organic EL display device 30c provided with a frame wiring line 22c including a thick line portion W and a bottom conductive layer B is given.

The organic EL display device 30c, like the organic EL display device 30a of the first embodiment, includes a display region D for displaying an image, defined in a rectangular shape, and the frame region F defined around the display region D.

The display region D of the organic EL display device 30c has the same configuration as in the organic EL display device 30a of the first embodiment.

The organic EL display device 30c includes, in the frame region F, the resin substrate layer 10, an insulating film 21 provided in contact with the front surface of the resin substrate layer 10, the frame wiring line 22c provided on the front surface of the insulating film 21, and a flattening film 13 provided as a protection film to cover the frame wiring line 22c.

The frame wiring line 22c is connected, via the first gate conductive layer 12ba, to a signal wiring line (for example, gate line, source line, and power supply line) of the organic EL element 19 in the display region D. The frame wiring line 22c is also connected to the second gate conductive layer 12bb provided to extend to the terminal section T. The frame wiring line 22c is formed with, for example, a metal layered film of a titanium film (with a thickness of approximately 100 nm)/an aluminum film (with a thickness of approximately 700 nm)/a titanium film (with a thickness of approximately 50 nm). As illustrated in FIG. 8, the frame wiring line 22c is provided to be bent in a wavy form to intersect multiple times at the bending section C with a pair of grooves 21a adjacent to each other in a plan view between the insulating film 21 and the flattening film 13. Further, as illustrated in FIG. 8, the frame wiring line 22c includes a thick line portion W formed at the bottom of the groove 21a thicker than the portions formed exterior to the groove 21a, and a bottom conductive layer B in a rod shape, which is formed at the bottom of the groove 21a thicker than the portions formed exterior to the groove 21a and extends in a direction in which the groove 21a extends. Note that the frame wiring line 22c is electrically connected to the bottom conductive layer B at the inner side of the groove 21a. Also, note that the frame wiring line 22c is provided to be bent in a wavy form to stride across, in a cross-sectional view, the neutral surface N of the layered body L over the insulating film 21.

The organic EL display device 30c described above has flexibility as the organic EL display device 30a of the first embodiment, and is configured, in each subpixel, such that the light-emitting layer 3 of the organic EL layer 16 is caused to appropriately emit light via the TFT 12 so that images are displayed.

The organic EL display device 30c of the third embodiment can be manufactured, by modifying the pattern shape of the frame wiring line 22a, in the method for manufacturing the organic EL display device 30a of the first embodiment.

As described above, according to the organic EL display device 30c of the third embodiment, the frame wiring line 22c intersects in a plan view with the pair of grooves 21a between the insulating film 21 and the flattening film 13, and thus, the frame wiring line 22c is provided to be bent in a wavy form to stride across, in a cross-sectional view, the neutral surface N of the layered body L. Accordingly, at the bending section C of the organic EL display device 30c, configurations in each of which the frame wiring line 22c being bent in a wavy form to stride across, in a cross-sectional view, the neutral surface N of the layered body L are to be successively provided in a direction obliquely intersecting the direction (short-side direction of the terminal section T) in which the frame wiring line 22c extends. This makes it possible to prevent breakages of the frame wiring line 22c in bending about bending axes being provided in the long-side direction and in the short-side direction of the terminal section T, thus making it possible to prevent breakages of the frame wiring line 22c in bending about an axis exactly orthogonal to a direction in which the frame wiring line 22c extends, as well as in bending about an axis not exactly orthogonal to a direction in which the frame wiring line 22c extends.

Further, according to the organic EL display device 30c of the third embodiment, the frame wiring line 22c includes the thick line portion W formed at the bottom of the groove 21a thicker than the portions formed exterior to the groove 21a, and the bottom conductive layer B in a rod shape, which is formed at the bottom of the groove 21a thicker than the portions formed exterior to the groove 21a and extends in a direction in which the groove 21a extends. This makes it possible to further reduce the wiring line resistance of the frame wiring line 22c and to further prevent breakage of the frame wiring line 22c.

### Other Embodiments

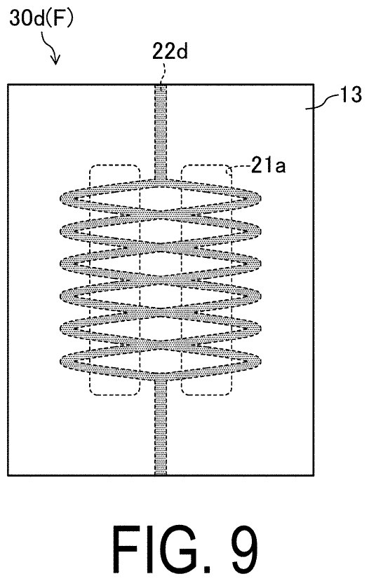

Although in the above-described embodiments, the frame wiring lines 22a to 22c are each provided in a wavy shape in a plan view in each of the organic EL display devices 30a to 30c, the frame wiring line may include a frame wiring line 22d as illustrated in FIG. 9. FIG. 9 is a plan view illustrating a frame region F of an organic EL display device 30d according to another embodiment. More specifically, the frame wiring line 22d is connected to a wiring line of the organic EL element 19 in the display region D. The frame wiring line 22d is formed with, for example, a metal layered film of a titanium film/an aluminum film/a titanium film. As illustrated in FIG. 9, the frame wiring line 22d is provided to be bent in a chain form to intersect multiple times in a plan view with a pair of grooves 21a between the insulating film 21 and the flattening film 13. The organic EL display device 30d of another embodiment, in which the frame wiring line 22d is provided in a chain form in a plan view, makes it possible to enhance the redundancy of the frame wiring line 22d.

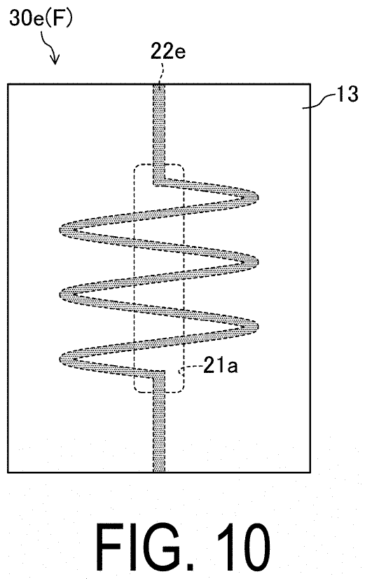

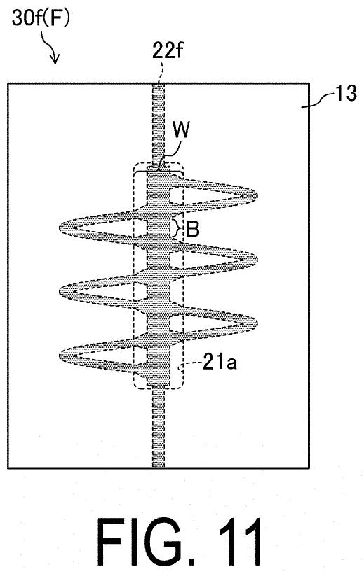

In the above-described embodiments, the example of a wiring line configuration in which a pair of grooves 21a is formed for one frame wiring line of the frame wiring lines 22a to 22d is given. However, as illustrated in FIG. 10 and FIG. 11, an example of a wiring line configuration in which one frame wiring line 22e and one frame wiring line 22f are each formed with one groove 21a may be given. FIG. 10 is a plan view illustrating a frame region F of an organic EL display device 30e according to another embodiment. More specifically, in the organic EL display device 30e, the frame wiring line 22e is connected to a wiring line of the organic EL element 19 in the display region D. The frame wiring line 22e is formed with, for example, a metal layered film of a titanium film/an aluminum film/a titanium film. As illustrated in FIG. 10, the frame wiring line 22e is provided to be bent in a wavy form to intersect multiple times in a plan view with a pair of grooves 21a between the insulating film 21 and the flattening film 13. In the meantime, FIG. 11 is a plan view illustrating a frame region F of an organic EL display device 30f according to another embodiment. More specifically, in the organic EL display device 30f, the frame wiring line 22f is connected to a wiring line of the organic EL element 19 in the display region D. The frame wiring line 22f is formed with, for example, a metal layered film of a titanium film/an aluminum film/a titanium film. As illustrated in FIG. 11, the frame wiring line 22f is provided to be bent in a wavy form to intersect multiple times in a plan view with a pair of grooves 21a between the insulating film 21 and the flattening film 13. Further, as illustrated in FIG. 11, the frame wiring line 22f includes a thick line portion W formed at the bottom of the groove 21a thicker than the portions formed exterior to the groove 21a, and a bottom conductive layer B in a rod shape, which is formed at the bottom of the groove 21a thicker than the portions formed exterior to the groove 21a and extends in a direction in which the groove 21a extends.

In the above-described embodiments, the example of the organic EL display device as a display device is given. However, the disclosure is applicable to a display device equipped with a plurality of light-emitting elements which are driven with current, for example, a display device equipped with quantum dot light-emitting diodes (QLEDs), which are light-emitting elements using quantum dot-containing layer.

Although in the above-described embodiments, the examples of the frame wiring lines 22a to 22d of single lines are given, the frame wiring lines 22a to 22d may each be made redundant by double lines extending in parallel with each other.

In the above-described embodiments, the example of the organic EL layer of the five-layer structure including the hole injection layer, the hole transport layer, the light-emitting layer, the electron transport layer, and the electron injection layer is given. It is also possible that, for example, the organic EL layer may include a three-layer structure including a hole injection-cum-transport layer, a light-emitting layer, and an electron transport-cum-injection layer.

In the above-described embodiments, the example of the organic EL display device including the first electrode as an anode and the second electrode as a cathode is given. However, the disclosure is also applicable to an organic EL display device, in which the layers of the structure of the organic EL layer are in the reverse order, with the first electrode being a cathode and the second electrode being an anode.

In the above-described embodiments, the example of the organic EL display device in which the electrode of the TFT connected to the first electrode serves as the drain electrode is given. However, the disclosure is also applicable to an organic EL display device in which the electrode of the TFT connected to the first electrode is referred to as the source electrode.

### INDUSTRIAL APPLICABILITY

As described above, the disclosure is useful for flexible display devices.

### REFERENCE SIGNS LIST

B Bottom conductive layer
C Bending section
D Display region
F Frame region
L Layered body
W Thick line portion
10 Resin substrate layer (resin substrate)
13 Flattening film (protection film)
19 Organic EL element (light-emitting element)
21a Groove
21 Insulating film
22a to 22f Frame wiring line
30a to 30f Organic EL display device

1-5. (canceled)

6: A display device comprising:
a resin substrate;
a light-emitting element configuring a display region provided on the resin substrate, the display region being formed in a rectangular shape;
a frame region provided around the display region;
a terminal section provided at an end portion of the frame region;
a bending section provided between the display region and the terminal section;
a frame wiring line provided in the frame region, the frame wiring line extending to the terminal section with being connected to the light-emitting element; and
a protection film provided to cover the frame wiring line,
wherein at the bending section, an insulating film with a groove formed on a surface of the insulating film is provided, the groove extending in a direction intersecting one side of the display region on the terminal section side,
the frame wiring line is provided, at the bending section, to be bent to intersect the groove between the insulating film and the protection film, and
the frame wiring line includes a thick line portion formed at a bottom of the groove thicker than a portion formed exterior to the groove.

7: The display device according to claim 6,
wherein the frame wiring line includes a bottom conductive layer formed at the bottom of the groove thicker than a portion formed exterior to the groove, the bottom conductive layer extending in a direction in which the groove extends.

8: The display device according to claim 7,
wherein the frame wiring line is electrically connected to the bottom conductive layer at an inner side of the groove.

9: The display device according to claim 6,
wherein the light-emitting element includes an organic EL element.

10: The display device according to claim 6,
wherein the resin substrate, the insulating film, and the protection film are each formed of a polyimide resin.

11: The display device according to claim 6,
wherein the insulating film is in contact with the resin substrate.

12: The display device according to claim 6,
wherein at the bending section, the frame wiring line is provided to be bent to stride across a neutral surface of a layered body including the resin substrate, the insulating film, and the protection film.

13: The display device according to claim 6,
wherein at least a pair of the grooves are provided to extend in parallel to each other, and
wherein the frame wiring line is provided to intersect plural times the pair of grooves.

14: The display device according to claim 6,
wherein the frame wiring line is provided in a wavy form in a plan view.

15: The display device according to claim 6,
wherein the frame wiring line is provided in a chain form in a plan view.
